(19) United States
(12) Patent Application Publication
(10) Pub. No.: US 2026/0173338 A1
(43) Pub. Date: Jun. 18, 2026

(54) METHOD FOR TRANSFERRING CHIPS ONTO A SUBSTRATE

(71) Applicant: COMMISSARIAT A L'ENERGIE ATOMIQUE ET AUX ENERGIES ALTERNATIVES, Paris (FR)

(72) Inventors: Sarah RENAULT, Grenoble Cedex 09 (FR); Adrien POIZAT, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/421,300

(22) Filed: Dec. 16, 2025

(30) Foreign Application Priority Data
Dec. 17, 2024 (FR) FR2414392

(51) Int. Cl. H05K 13/00; H05K 13/04

(52) U.S. Cl. CPC H05K 13/0015; H05K 13/046

(57) ABSTRACT

A method for transferring a set of chips onto a substrate is disclosed. The method includes providing a support having a bottom extending parallel to a main plane and a rim including a first panel forming a first wedge and a second panel forming a second wedge. A first chip is placed on the bottom and a force is applied to slide the first chip until it abuts both panels. A second chip is placed on the bottom and slid until it abuts the first panel and a secondary edge of the first chip. The chips are immobilized in the main plane and transferred onto the substrate.

### TECHNICAL FIELD

The present invention relates to the field of electronics. It relates, quite specifically, to a method for transferring chips onto a substrate. The invention has, as particularly advantageous applications, fields as varied as sensors and imagers.

### PRIOR ART

Electronic chips are used in lots of fields, including microelectronics and optoelectronics. In all these fields, chips are generally transferred onto substrates, enabling various functionalities, including electric interconnections and mechanical, optical and/or thermal recoveries. The substrates can be electronic boards (commonly called “PCB” (Printed Circuit Board), metal casings, or also ceramic casings. The features of the substrate on which the chips are transferred are functions of specifics of each chip.

In order to perform the transfer, chips can, in particular, have balls on their rear face and be returned and transferred onto the substrate (flip chip). These chips can be very large (for example, 12 mm×12 mm). These chips can be made of silicon or any other material according to their function.

To produce very resolute devices (for example, sensors or imagers), a solution is to produce one single large monolithic chip. However, manufacturing these large monolithic chips has a low yield. This technique is therefore not optimal.

An alternative is to manufacture several chips, smaller, which have a better manufacturing yield, and to abut them to one another. The main problem in this technique is to abut the chips as close as possible to one another, or in contact with one another, in order to limit the dead zones between the chips. Currently, to abut chips, the latter are removed by the arm of a piece of equipment and positioned one by one on the substrate. This method however has numerous disadvantages. First, this hybridisation mode is limited by the positioning accuracy of the equipment, which is currently around +/−0.5 μm. Moreover, this hybridisation mode is long in the case where numerous chips must be abutted: for example, a 5×5 chip matrix can require numerous hours to be disposed on the substrate. Finally, this hybridisation mode is risky, as if one of the hybridisations occurs poorly, this leads to the sacrifice of all the chips already hybridised, given that it is particularly difficult to cleanly remove a chip to hybridise another one.

Another solution is to use a mass reflow method, where the components are left free and self-align on their receiving pads when the material of the interconnections passes to the liquid state during heating. However, the positioning accuracy of the receiving pads does not make it possible to use this self-alignment phenomenon on all the substrate, it is, in particular, the case for large ceramic substrates.

An aim of the present invention is therefore to propose a method for transferring chips onto a substrate, resolving at least some of the problems outlined above. Preferably, the method can be used over a wide range of substrates, preferably all the substrates commonly used in microelectronics and optoelectronics. Preferably, the method will have a better yield that the methods of the prior art. Advantageously, the method will enable an accuracy as least equal to and preferably greater than the accuracy of the methods currently used. The method will advantageously make it possible to reduce the dead zones between chips. The method will advantageously make it possible to reduce the risk of the process, and to reduce the assembly time.

### SUMMARY

To achieve this aim, according to an embodiment, a method for transferring a set of chips onto a substrate is provided, the method being characterised in that it comprises:
a. a provision of a support comprising a bottom extending parallel to a main plane and a rim projecting from the bottom, the rim comprising at least one first pan panel forming a second wedge, the first panel and the second panel mainly extending, projecting over the main plane, respectively along a first direction and along a second direction distinct from the first direction,
b. an arrangement in the support of a first chip of the set of chips, with:
   i. a placement of the first chip on the bottom of the support,
   ii. an application of a force to the first chip, so as to make it slide abutted against the first panel and against the second panel of the rim,
c. an arrangement in the support of a second chip of the set of chips, with:
   i. a placement of the second chip on the bottom of the support,
   ii. an application of a force to the second chip, so as to make it slide abutted against the first panel of the rim and against an edge, called secondary edge, of the first chip,
d. an immobilisation of the first chip and of the second chip in the main plane,
e. a transfer of each arranged chip onto the substrate.

Thus, the first and second panels act as wedges during the arrangement of the chips. The currently existing techniques make it possible to manufacture these wedges and to orient them against one another with a great accuracy. These wedges thus enable an accurate positioning of the different chips.

The fact of being able to flatten the chips against the panels moreover makes it possible to highly reduce the dead zones between the chips. The positioning of a chip with respect to the adjacent chip is indeed no longer dependent on the accuracy of a piece of equipment. The chips are flattened against one another by application of a force in the direction of the rim of the support. By applying a sufficient force, the chips come into contact with one another. Thus, thanks to the method according to the invention, the dead zones are almost inexistant, even completely inexistant.

According to an embodiment, the immobilisation of the chips is achieved using a liquid spread over the bottom of the support, by utilising the suction effect between the bottom of the support and the chips. Using the liquid limits the degradation of the chips by scratching with the bottom during their arrangement. Moreover, the suction effect between the bottom of the support and the chips enables a very good holding of the chips at their desired positioning.

The steps of arranging the chips within the support can moreover be done by hand. Making the chips slide abutted against the panels indeed does not require as much accuracy from the operator, nor from the equipment, than in the prior art. The accuracy of the positioning comes from the accuracy of the geometry of the rim of the support. It is therefore not necessary to use a controlled arm to position the chips. This makes it possible to reduce the cost of the method, but also to very highly reduce the time necessary for transferring the chips onto the substrate. As an example, the one-to-one hybridisation of the chips of a 5×5 matrix on a substrate using a controlled arm, can take several days. The arrangement of the chips in the support, then the transferring onto the substrate of the arranged chips, according to the method according to the invention, only takes around one hour.

Moreover, the method according to the invention makes it possible to substantially align all of the upper faces of the chips in one single and same plane. This plane typically corresponds to the gripping face of the tool used for the transfer (that this is a transfer arm or directly the transfer substrate). The method according to the invention thus further enables an arrangement of the chips in the longitudinal plane, their accurate positioning along the vertical and thus makes it possible to obtain an excellent flatness of all of the upper faces of the chips.

Furthermore, the method according to the invention can be implemented on any type of substrate, without constraint in terms of materials or surface area.

The transfer method according to the invention is therefore easy to implement, more economic and a lot less time-consuming than the methods used up to now. It further makes it possible to highly reduce the dead zones between the chips. Overall, the method according to the invention has a lot greater yield than the current methods.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1A is a top view of the support used in the method according to the invention.

FIG. 1B is a perspective view of the support used in the method according to the invention.

FIGS. 2A to 2D illustrate the successive arrangement of chips in the support by the method according to the present invention.

FIGS. 3A and 3B represent a set of arranged chips in the support.

FIG. 4 illustrates an example of arms being able to be used for transferring onto a substrate of the arranged chips in the support.

The drawings are given as examples and are not limiting of the invention. They constitute principle schematic representations intended to facilitate the understanding of the invention, and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to a preferred example, the first panel and the second panel of the rim do not touch.

According to a preferred example, the rim has a panel called distant panel, connecting the first panel and the second panel, and the shape of which, projecting into the main plane deviates from a shape consisting of the extension of the first panel and of the second panel up to their intersection, the portion thus forming a clearing.

According to a preferred example, the distant panel has, projecting into the main plane, a circular arc shape, the extrados of which is rotated towards the outside of the support.

According to a preferred example, the arrangement of the first chip is such that when two adjacent edges of the first chip, called main edges, forming a corner of the first chip, are in contact with the first panel and with the second panel, said corner of the first chip is not in contact with the rim.

According to an example, the rim forms a closed contour projecting into the main plane.

According to an embodiment, the immobilisation of the first chip and of the second chip in the main plane comprises:
a. before the arrangement in the support of the first chip and of the second chip, an arrangement of a liquid on the bottom of the support,
b. during the arrangement in the support of the first chip, placing the first chip on the bottom of the support, such that some of the liquid extends between the bottom and the first chip,
c. during the arrangement in the support of the second chip, placing the second chip on the bottom of the support, such that some of the liquid extends between the bottom and the second chip,
d. after the arrangement in the support of the first chip and of the second chip, an application to each from among the first chip and the second chip of a force directed towards the bottom of the support, so as to drive out at least partially, the liquid present between said chip and the bottom of the support.

Pressing the chip against the bottom of the support makes it possible to increase the suction effect between the bottom of the support, the liquid and the chip. The chip is thus well flattened against the bottom of the support, and well held in the desired position.

Advantageously, the step of arranging the liquid on the bottom of the support is repeated several times during the arrangement of the chips in the support. Adding liquid during the method makes it possible to overcome the evaporation of the liquid, in particular, the liquid not covered by the chips. All the chips thus benefit from the presence of the liquid to be flattened against the bottom of the support by suction effect.

According to an example, the liquid is chosen from among the following liquids: ethanol, isopropyl alcohol, water, acetone, a deoxidising flux. The liquid can be chosen for various properties and, in particular, for its deoxidising properties, in particular, when the chips have certain soldering materials. This is, in particular, advantageous, when balls, for example, indium balls, are present at the chips. Isopropyl alcohol, in particular, has deoxidising properties being able to be utilised.

According to an embodiment, the step of immobilising the first chip and the second chip in the main plane comprises:
a. during the arrangement in the support of the first chip, having an adhesive agent between the bottom and the first chip,
b. during the arrangement in the support of the first chip, having an adhesive agent between the bottom and the second chip.

According to a preferred example, the step of transferring each arranged chip onto the substrate comprises a heating of the support.

According to an embodiment, the step of immobilising the first chip and the second chip in the main plane comprises a flattening of the first chip and of the second chip against the bottom of the support by suctioning.

According to an example, the method further comprises an arrangement in the support of a third chip from the set of chips, with:
a. a placement of the third chip on the bottom of the support,
b. an application of a force to the third chip, so as to make it slide abutted:
   i. against the first panel and against an edge called secondary edge of the first chip, or
   ii. against the second panel and against an edge of the second chip,
c. an immobilisation of the third chip in the main plane.

According to an embodiment, along a third direction perpendicular to the main plane:
a. the chips to be transferred have a thickness e₂₀, the thickness e₂₀ being measured when the chips are placed on the bottom of the support,
b. the rim has a height h₁₂,
   with h₁₂<e₂₀.

According to an embodiment, the step of transferring the set of arranged chips onto the substrate comprises the following step:
a. while the set of arranged chips is located in the support, bringing the substrate onto the set of arranged chips.

According to an embodiment, the step of transferring the set of arranged chips onto the substrate comprises the following steps:
a. removing from the support, the set of arranged chips using an arm,
b. depositing the set of arranged chips onto the substrate, the arm being configured to enable the preservation of the relative positioning of the chips from the set of arranged chips during these steps taking place.

According to an example, the arm is configured to suction each of the arranged chips.

Preferably, the first direction and the second direction are perpendicular. This is advantageous in the typical case of rectangular or square chips.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first element on a second element, does not compulsorily mean that the two elements are directly in contact with one another, but means that the first element covers, at least partially, the second element by being, either directly in contact with it, or by being separated from it by at least one other element.

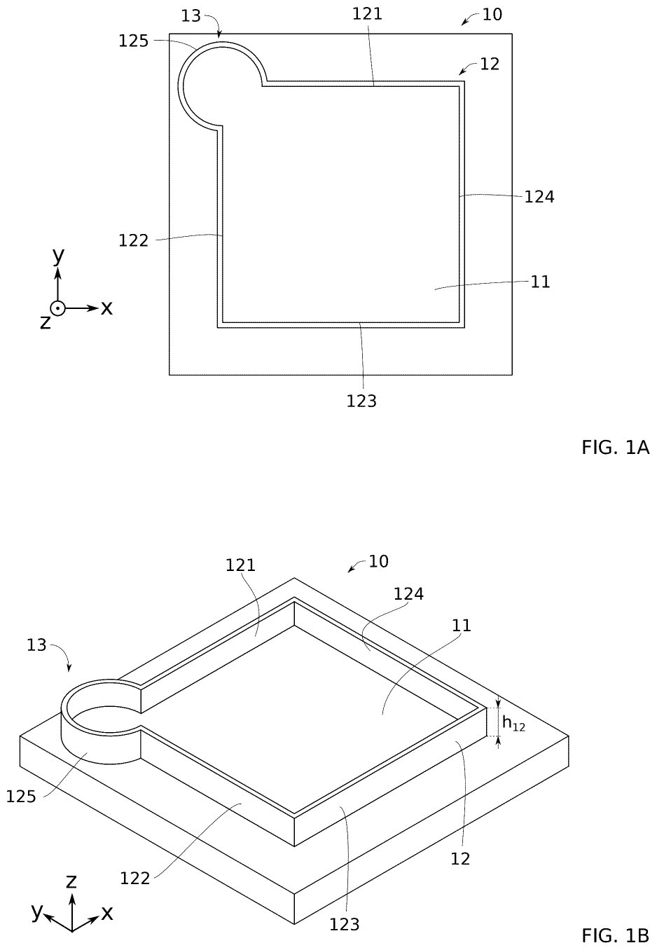

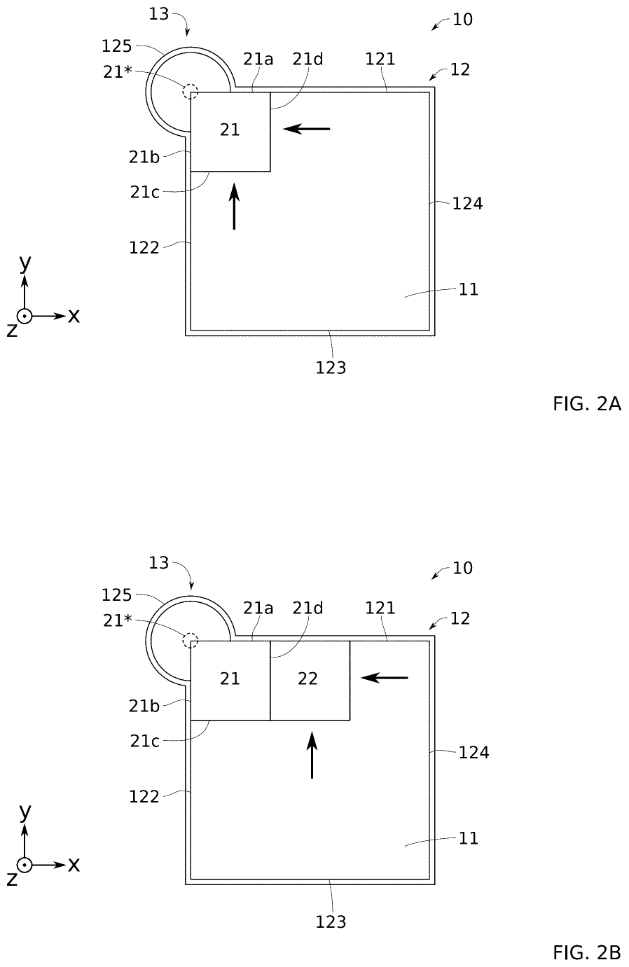

A preferably orthonormal system, comprising the axes X, Y, Z is represented in FIGS. 1A, 1B and 2A. This system is applicable by extension to the other figures. In the present patent application, thickness will preferably be referred to for a layer or a wafer, and height will preferably be referred to for a structure or a device. The height is taken perpendicularly to the main plane XY. The thickness is taken along a direction normal to the main extension plane of the layer or of the wafer. Thus, a layer/wafer typically has a thickness along the third direction Z, when it extends mainly along the main plane XY, and a projecting element, for example, a trench or a tab, has a height along the third direction Z. The relative terms “on”, “under”, “underlying”, “above”, “below” refer, unless otherwise mentioned, to positions taken along the direction Z.

The terms “substantially”, “around”, “about” mean “plus or minus 10%, preferably plus or minus 5%”.

The method according to the invention uses a support 10 illustrated in FIGS. 1A and 1B. The support 10 has a bottom 11 and a rim 12 extending projecting from the bottom 11. The bottom 11 extends parallel to a main plane XY. The rim 12 is typically substantially perpendicular to the bottom 11. The rim 12 of the support 10 has a height h₁₂ measured along the third direction Z perpendicular to the main plane XY.

The rim 12 comprises, as a minimum, a first panel 121 and a second panel 122. These two panels 121, 122 form wedges which will serve, during the implementation of the method, to correctly position the chips.

Projecting into the main plane XY, the first panel 121 extends substantially along a first direction X and the second panel 122 along a second direction Y. By “the panel extends substantially along a direction”, it is understood that the general shape of the panel is elongate along this direction. Typically, the panel is parallel to this direction. It is however not excluded that the panel has deviations with respect to this general direction. It can, for example, be considered that the panel has removals in the direction perpendicular to its main extension direction, for example, in the form of slots. It is, for example, possible to size the panel, such that the contact between the neighbouring chip and the panel considered is made at two supporting zones. This can make it possible to limit the contact surface between the chips and the rim and thus limit the degradation of the chips. A panel can also not be continuous and have through openings in the direction perpendicular to its main extension direction. Such openings also make it possible to limit the contact surface between the chips and the rim. The openings in the panels further make it possible to more easily discharge the surplus liquid used for holding chips in their respective arranged positions (see below).

Preferably, the first panel 121 and the second panel 122 are perpendicular to one another. This is advantageous for positioning rectangular or square chips.

The rim 12 optionally comprises a third panel 123 and a fourth panel 124. Advantageously, the panels 121, 122, 123, 124 of the rim 12 are perpendicular in pairs. The rim 12 thus has, projecting into the main plane XY, a general rectangular, or square shape.

The rim 12 preferably further comprises a distant panel 125 connecting the first panel and the second panel 122. The distant panel 125 forms a clearing 13 with respect to the general shape of the rim 12. The distant panel 125 forms a non-closed contour connected, on the one hand, to the first panel 121 and, on the other hand, to the second panel 122. This non-closed contour includes the corner which would have been formed if the first panel 121 and the second panel 122 had been extended up to their intersection. The rim 12 thus defines a periphery of the support 10, larger than if the first and second panels 121, 122 had simply been extended up to their intersection. The distant panel 125 typically has a circular arc shape. The intrados of the distant panel 125 is thus located facing the rest of the support 10. Its extrados is rotated towards the outside of the support 10.

As will appear during the description of the method according to the invention, the clearing 13 formed by the distant panel 125 makes it possible to limit the damage of the corner of the first chip 21 arranged in the support 10.

According to another embodiment not illustrated, the rim 12 does not comprise the distant panel 125 and the rim 12 forms an open contour between the first panel 121 and the second panel 122. The absence of a corner formed by the first panel 121 and the second panel 122 also makes it possible to limit the damage of the corner of the first chip 21 during its arrangement in the support 10. The absence of a corner formed by the first and second panels 121, 122 also makes it possible to more easily discharge the surplus liquid used for holding the chips in their respective arranged positions (see below).

Advantageously, the panels, and in particular, the first and second panels 121, 122, allow an opening or form a removal with respect to their main extension direction at the angles of the chips when these are in their respective arranged positions. This makes it possible to limit the degradation of the chips at their corners.

In the two examples described above, it is understood that the space between the first panel 121 and the second panel 122 is sized, so as to enable that these two panels 121, 122 act simultaneously abutted for the first chip 21 placed in the support 10, as will be described more below.

It is understood that the shape of the rim 12 described above is given as an example, and that it is possible to use a support 10, the rim 12 of which has another geometry. The geometry illustrated in FIGS. 1A and 1B is however the preferred geometry for the implementation of the method according to the invention.

The support 10 can be made of silicon or of stainless steel. The bottom 11 can, for example, be a silicon wafer. The different panels 121, 122, 123, 124 of the rim 12 can be silicon wedges. These wedges can have been bonded to the silicon substrate forming the bottom 11. They can also have been manufactured directly on the wafer by an etching method. It is also possible that the wedges forming the panels had simply been deposited on the bottom 11. The support 10 can also be obtained by mechanical machining, for example, by a silicon carbide SiC tool.

Different embodiments of the method according to the invention will now be described in detail, in reference to FIGS. 2A to 2D.

A first step of the method is the provision of a support 10 such as described above.

According to a first main embodiment, liquid is then deposited in the support 10, on the bottom 11. This liquid can be chosen from among: ethanol, isopropyl alcohol, water, acetone. This liquid can also be a flux making it possible to deoxidise the metal pads of the chips.

The liquid can be deposited in the form of drop(s) on the bottom 11 of the support 10. It is also possible to implement a flow of the liquid. The liquid thus forms a flux on the bottom 11 of the support 10.

Then, the arrangement of a first chip 21 in the support 10 is proceeded with, as illustrated in FIG. 2A. This arrangement is achieved in the same way.

The first chip 21 is placed on the bottom 11 of the support 10. Preferably, the first chip 21 is placed on the bottom 11 of the support 10, such that the liquid extends between the bottom 11 and the chip 21. The first chip 21 can be deposited using a clamp such as forceps or also a suction pen, which enables a very good preservation of the chips during the operation.

The first chip 21 is then moved to its arranged position. To do this, a force is applied on the first chip 21, making it possible to move it until it is located abutted, both against the first panel 121 and against the second panel 122 of the rim 12. The arrows represented in FIG. 1A illustrate the fact that in the case illustrated, this force has a component along the first direction X and a component along the second direction Y.

During its movement to its arranged position, the first chip 21 slides over the bottom 11, thanks to the lateral force applied. The liquid makes it possible to limit the damage of the chip by friction with the bottom 11 of the support 10.

The application of the force on the first chip 21 can be done by hand by a user. The movement of the first chip 21 can optionally be done in two steps: a first step intended to abut the first chip 21 against the first panel 121, and a second step making it possible to abut it against the second panel 122, by making it slide against the first panel 121. It is however thus preferable to apply, again, a force on the first chip 21, so as to correctly flatten it against the two panels 121, 122. It is also possible to successively apply, several times, a force along the first direction X and along the second direction Y.

Thus, the configuration illustrated in FIG. 2A is obtained: the first chip 21 is abutted both against the first panel 121, and the second panel 122. More precisely, a first edge 21a of the first chip 21 is in contact with the first panel 121 and a second edge 21b of the first chip 21 is in contact with the second panel 122 of the rim 12. It is thus held in place by suction effect.

As illustrated in FIG. 2A, thanks to the clearing 13, the corner 21* of the first chip 21 formed by its first edge 21a and its second edge 21b is free. In other words, it is not in contact with the rim 12. Indeed, if the first panel 121 and the second panel 122 were extended up to forming an angle (typically a right angle), the corner 21* complementarily would come from this angle. Yet, if the force applied on the first chip 21 was incorrectly directed and/or was applied with too much intensity, or due to the manufacturing tolerances of the chips and of the support, the corner 21*, which is a weak point of the first chip 21, could be damaged. The clearing 13 therefore makes it possible to limit the degradation of the first chip 21 at this corner 21*. Moreover, it is noted that the first chip 21 also undergoes forces directed against the first panel 121 and the second panel 121 when the other chips are arranged. Indeed, as will further appear, the first chip 21 itself subsequently serves as an abutment to the other chips and/or serves as a support point to other chips which will themselves act as an abutment. The clearing therefore makes it possible to protect the corner 21* all throughout the method.

The method moreover comprises a step of arranging a second chip 22 (FIG. 2B). The arrangement of the second chip 22 is done according to the same principle as that of the first chip 21, except for the fact that the second chip 22 does not come into contact directly with the two panels 121, 122, but abuts, on the one hand, against one from among the first panel 121 and the second panel 122, and on the other hand, abuts against an edge of the first chip 21. In the example illustrated in FIG. 2B, the second chip 22 abuts against the first panel 121 and against the edge referenced 21d of the first chip 21.

Thus, during this step, the first chip 21 acts as an abutment for the second chip 22.

The movement of the second chip 22 is performed similarly to that of the first chip 21: the second chip 22 is placed on the liquid disposed on the bottom 11 of the support 10, then is slid up to its arranged position.

Thus, the configuration illustrated in FIG. 2B is obtained.

The successive arrangement of the first chip 21 and of the second chip 22 can be done sequentially: first, the complete arrangement of the first chip 21, then the complete arrangement of the second chip 22. This is the preferred embodiment and that illustrated in FIGS. 2A and 2B. It is however understood that it can be considered that the arrangement of the first chip 21 and that of the second chip 22 are done parallel. For example, it is possible to flatten the first chip 21 against the first panel 121, flatten the second chip 22 against the second panel 121, then flatten the assembly formed of the first chip 21 and of the second chip 22 against the second panel 122.

The method can comprise the arrangement of other chips. FIGS. 2C and 2D illustrate the arrangement of a third chip 23 and of a fourth chip 24.

The third chip 23 can be positioned at two distinct locations: or, abutted against the second panel 122 and against a secondary edge 21c of the first chip 21 (example illustrated in FIG. 2C), or abutted against the first panel 121 and against an edge 22d of the second chip 22. In both cases, the arrangement of the third chip 23 is done, as for the preceding chips 21, 22: the third chip 23 is placed on the liquid and is slid on the bottom 11 of the support 10 up to its arranged position.

During this step, the first chip 21 or the second chip 22 acts as an abutment for the third chip 23.

Several positions are also possible for the fourth chip 24 (in contact with the first panel 121, in contact with the second panel 122, only in contact with chips arranged beforehand). FIG. 2D illustrates the example in which the second and third chips 22, 23 each have been placed against a distinct panel 121, 122 and in which the fourth chip 24 comes to be placed abutted against each of these two chips 22, 23. The fourth chip 24 is thus located in contact with the edge referenced 22c of the second chip 22 and in contact with the edge referenced 23d of the third chip 23.

In this example, both the second chip 22 and the third chip 23 act as an abutment for the fourth chip 24.

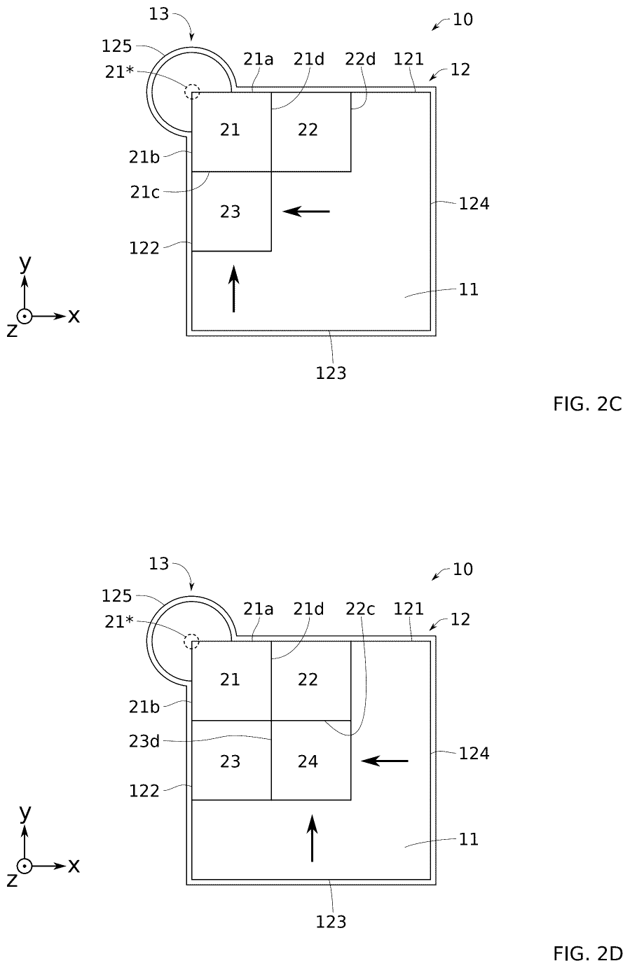

The method can thus continue for any number of chips, for example, a 3×3 matrix, that is a matrix of nine chips. FIG. 3A (perspective view) and 3B (top view) illustrate such a matrix of nine chips 21, 22, 23, 24, 25, 26, 27, 28, 29 arranged in the support 10.

Preferably, the support 10 and, in particular, the rim 12 will have been sized larger than the size of the final matrix of chips. In particular, as illustrated in FIGS. 3A and 3B, preferably, there is a clearance between the chips 25, 26, 27, 28, 29 on the one hand, and the second and third panels 123, 124 on the other hand. This clearance facilitates the handling of the chips.

Generally, the arrangement of the set of chips to be transferred can be done by arranging each chip 21, 22, . . . 29 in the support 10 with:
a. a placement of the chip 21, 22, . . . 29 on the bottom 11 of the support 10, such that some of the liquid extends between the bottom 11 and the chip 21, 22, . . . 29,
b. an application of a force to the chip 21, 22, . . . 29 so as to make it slide until it is stopped by the first panel 121 and by the second panel 122 of the rim 12, optionally through one or more chips 21, 22, . . . 29 arranged beforehand in the support 10.

Advantageously, when a chip is arranged in the correct location, a force directed towards the bottom 11 of the support 10 is applied on the chip. This makes it possible to create a suction effect between the bottom 11, the liquid and the chip. This suction effect makes it possible to hold the chip in place.

Moreover, preferably, liquid is added several times on the bottom 11 of the support 10, in order to have liquid available for the arrangement of all the chips.

As explained above for the arrangement of the two first chips 21, 22, it is possible to perform, in parallel, the arrangement of several chips of the set of chips 21, 22 . . . 29.

The third panel 123 and/or the fourth panel 124 can moreover serve to push the set of chips into abutment against the first panel 121 and the second panel 122. In this example, the third and fourth panels 123, 124 are removable with respect to the bottom 11. The operator or the equipment can use these panels to simultaneously push several chips placed on the bottom 11 of the support 10 and ensure that these are correctly arranged. This step is typically carried out once all the chips are disposed on the bottom 11 of the support 10.

The chips have a thickness e₂₀ measured along the third direction Z. The thickness e₂₀ can be greater than the height h₁₂ of the rim 12, as illustrated in FIG. 3A. For example: e₂₀=250 μm and h₁₂=180 μm. e₂₀ can also be less than h₁₂. This is a scenario which can be perfectly considered in the case of very thin chips, for example; in this case, the rim must thus be removable, in order to be able to remove the chips.

The method further comprises a step of transferring the set of arranged chips onto a substrate. Advantageously, all the arranged chips are transferred simultaneously onto the substrate.

This transfer step can be carried out in different ways.

According to a first example, during this step, the arranged chips are held in the support 10 and the substrate is returned and brought against the chips to perform the transfer. In this example, it is preferable that e₂₀≥h₁₂, such that the chips are more easily accessible.

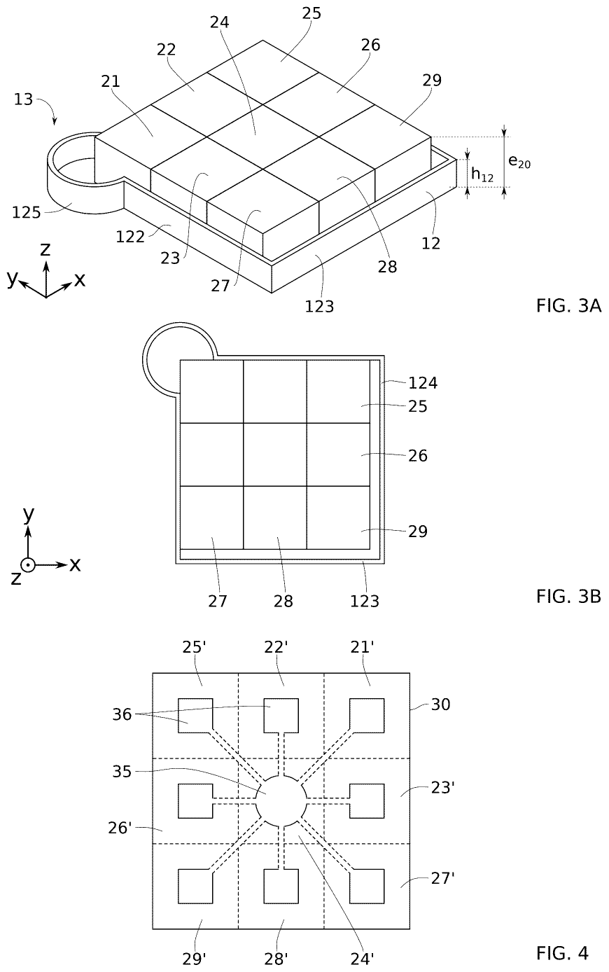

According to a second example, an arm is used to extract the arranged chips from the support 10 and to bring them onto the substrate. The arm is thus configured to hold the relative position of the arranged chips during the transfer. A schematic, cross-sectional view of an example of an arm being able to be used during this step is presented in FIG. 4. The arm can comprise a suction system configured to suction and hold each of the chips against a tool 30, typically located at the end of the arm. The tool 30 can thus have openings 35, 36 through which the chips are suctioned. Typically, the tool 30 has a main opening 36, intended to face a chip and connected through thin openings to a plurality of secondary openings 35, each intended to face a distinct chip. The references 21′, 22′, 23′, 24′, 25′, 26′, 27′, 28′and 29′of FIG. 4 illustrate the placement against the tool 30 intended for each of the chips 21, 21, 23, 24, 25, 26, 27, 28 and 29.

In this second example, the chips can also both extend beyond the rim 12 along the third direction Z (e₂₀>h₁₂) and be recessed with respect to the rim 12 (e₂₀<h₁₂) or be at the same level (e₂₀=h₁₂). This will depend on the dimensions of the tool against which the chips are suctioned.

According to another embodiment, the support 10 is mounted on an arm such as described above. The suctioning of the chips by the arm is thus activated once the chips are arranged. The transfer onto the substrate is thus done directly by moving the arm facing the substrate and deactivating the suctioning.

Preferably, during the transfer step, the support 10 is heated. This makes it possible to reduce, even remove the suction effect of the chips arranged against the bottom 11 of the support 10 and facilitates their transfer onto the substrate.

To facilitate the removal of the chips from the support 10, it is also possible to provide that the bottom 11 of the support 10 has a certain roughness. The roughness of the support 10 will thus make it possible to limit the suction effect.

The method has been described until now, for a first main embodiment, in which the immobilisation of the chips in their respective arranged positions is done using a liquid spread over the bottom 11 of the support 10. Other embodiments can however be considered to immobilise the chips at the time of them being transferred onto the substrate.

According to a second main embodiment, an adhesive agent is disposed between the chips 21, 22 . . . 29 and the bottom 11 of the support 10. The adhesive agent can be applied on the chips, on the bottom 11 or on both, before the placement of the chips in the support 10.

The adhesive agent can, in particular, be a glue, an adhesive gel, an adhesive strip.

Preferably, the properties of the adhesive agent (its viscosity, in particular) make it possible to move the chips to their arranged position. Thus, the chips 21, 22 . . . 29 can be placed on the bottom 11 of the support 10 and be slid on this bottom 11 through the adhesive agent.

As in the first main embodiment, preferably, to facilitate the detachment of the chips from the support 10 and their transfer onto the substrate, the support 10 is heated. Preferably, the support 10 is heated to a temperature at least equal to the melting point of the adhesive agent.

According to a third main embodiment, the chips are flattened against the bottom 11 of the support 10 by suctioning. This suctioning is typically done vacuumed. In this embodiment, the suctioning is maintained all throughout the transfer of the chips onto the substrate. In the scope of this embodiment, it will be preferred to transfer chips onto the substrate by bringing the substrate onto the chips.

It is understood that all the features described in the scope of the first main embodiment apply to the second and third main embodiments.

Regarding the different embodiments described above, it appears that the present invention proposes an effective solution for transferring chips onto a substrate.

The invention is not limited to the embodiments described above, and extends to all the embodiments covered by the invention.

1-16. (canceled)

17. A method for transferring a set of chips onto a substrate, the method comprising:
providing a support having a bottom extending parallel to a main plane and a rim projecting from the bottom, the rim including a first panel forming a first wedge and a second panel forming a second wedge, the first panel and the second panel extending mainly along respective first and second directions distinct from one another in the main plane;
placing a first chip of the set of chips on the bottom of the support;
applying a force to the first chip to slide the first chip until the first chip abuts both the first panel and the second panel of the rim;
placing a second chip of the set of chips on the bottom of the support;
applying a force to the second chip to slide the second chip until the second chip abuts the first panel of the rim and a secondary edge of the first chip;
immobilizing the first chip and the second chip in the main plane; and
transferring the first chip and the second chip onto the substrate.

18. The method of claim 17, wherein the first panel and the second panel of the rim do not touch.

19. The method of claim 17, wherein the rim includes a distant panel connecting the first panel and the second panel, the distant panel having a shape in projection onto the main plane that deviates from an extension of the first panel and the second panel to their intersection so as to form a clearing.

20. The method of claim 19, wherein the distant panel has, in projection onto the main plane, a circular-arc shape with an extrados oriented outward from the support.

21. The method of claim 17, wherein placement of the first chip is such that, when two adjacent main edges of the first chip forming a corner of the first chip are in contact with the first panel and the second panel, the corner of the first chip is not in contact with the rim.

22. The method of claim 17, wherein immobilizing the first chip and the second chip in the main plane comprises:
before arranging the first chip and the second chip, applying a liquid to the bottom of the support;
placing the first chip on the bottom such that the liquid extends between the bottom and the first chip;
placing the second chip on the bottom such that the liquid extends between the bottom and the second chip; and
after arranging the first chip and the second chip, applying a force directed toward the bottom to each of the first chip and the second chip to at least partially expel the liquid between each of the first chip and the second chip and the bottom.

23. The method of claim 22, further comprising repeatedly applying the liquid to the bottom of the support during arrangement of the first chip and the second chip in the support.

24. The method of claim 22, wherein the liquid comprises ethanol, isopropyl alcohol, water, acetone, or a deoxidizing flux.

25. The method of claim 17, wherein immobilizing the first chip and the second chip in the main plane comprises providing an adhesive agent between the bottom and the first chip, and between the bottom and the second chip.

26. The method of claim 17, wherein transferring the first chip and the second chip onto the substrate comprises heating the support.

27. The method of claim 17, wherein immobilizing the first chip and the second chip in the main plane comprises flattening the first chip and the second chip against the bottom of the support by suction.

28. The method of claim 17, further comprising:
placing a third chip of the set of chips on the bottom of the support;
applying a force to the third chip to slide the third chip until the third chip abuts (i) the first panel and a secondary edge of the first chip, or (ii) the second panel and an edge of the second chip; and
immobilizing the third chip in the main plane.

29. The method of claim 17, wherein, along a direction perpendicular to the main plane, the first chip and the second chip to be transferred have a thickness e₂₀ and the rim has a height h₁₂, and h₁₂ is less than e₂₀.

30. The method of claim 17, wherein transferring the first chip and the second chip onto the substrate comprises bringing the substrate onto the first chip and the second chip while the first chip and the second chip remain in the support.

31. The method of claim 17, wherein transferring the set of arranged chips onto the substrate comprises:
removing, using an arm, the first chip and the second chip from the support while maintaining relative positioning among the first chip and the second chip; and
depositing the first chip and the second chip onto the substrate.

32. The method of claim 31, wherein the arm is configured to suction each of the first chip and the second chip.
